(19) United States
(12) Patent Application Publication
(10) Pub. No.: US 2024/0401223 A1
(43) Pub. Date: Dec. 5, 2024

(54) DISCOVERY OF DOUBLE HELIX AND IMPACT ON NANOSCALE TO MESOSCALE CRYSTALLINE STRUCTURES

(71) Applicant: North Carolina State University, Raleigh, NC (US)

(72) Inventors: Jagdish Narayan, Raleigh, NC (US); Roger Narayan, Raleigh, NC (US)

(21) Appl. No.: 18/678,177

(22) Filed: May 30, 2024

Related U.S. Application Data
(60) Provisional application No. 63/469,876, filed on May 31, 2023.

(51) Int. Cl. C30B 1/02; C30B 29/66

(52) U.S. Cl. CPC C30B 1/02; C30B 29/66

(57) ABSTRACT

Screw dislocations play a significant role in the growth of crystalline structures by providing a continuous source of surface steps, which represent available sites for crystal growth. Here we show that pure screw dislocations can become helical by the absorption of defects (e.g., vacancies), and develop attractive interaction with another helical dislocation to form a double helix of screw dislocations. These single and double helix of screw dislocations can result in the formation of interesting nanostructures with large Eshelby twists. Examples of the formation of a double helix during thermal annealing of screw dislocations in magnesium oxide are presented. These large effective Burgers also unravel the mechanism for the formation of nanopipes and micropipes with hollow cores and nanotubes with Eshelby twists in technologically important materials, such as SiC, GaN and ZnO that are utilized in a variety of advanced solid state devices.

### CROSS-REFERENCE

This application claims the benefit of Provisional Application No. 63/469,876, filed on May 31, 2023, which is incorporated herein by reference in its entirety.

This invention was made with government support under grant number DMR2016256 awarded by the National Science Foundation. The government has certain rights in the invention.

### TECHNICAL FIELD

The invention relates to improvement in crystal growth. More specifically, the invention relates to the formation of single and double helices of screw dislocations to change the properties of materials utilized in a variety of advanced solid stating devise.

### BACKGROUND

Screw dislocations with Burgers vectors parallel to dislocation lines play a critical role in crystal growth across the scale ranging from nanostructures to large crystalline structures as well as in determining the properties of solid state materials. The creation of a screw dislocation can be visualized by partially slicing into a crystal along a specified plane and then displacing one face with respect to the other by a lattice (Burgers) vector. The boundary of this cut represents a screw dislocation along which lattice planes are arranged in a helical way. This helical structure can provide a continuous source of surface steps for crystal growth along the axes of screw dislocations. This concept, originally proposed by Sir Charles Frank, solved a longstanding challenge in materials science and explained crystal growth at supersaturations as low as 1%. Without these dislocations, crystal growth from the vapor phase required supersaturations exceeding 1.5. The crystal growth velocity is directly proportional to the fraction of sites available for attachment during crystal growth, which can be provided by the steps associated with emerging screw dislocations. This self-seeding crystal growth mechanism is applicable across the scale ranging from nanowires to whiskers. Moreover, it can overcome the utilization of catalysts for the growth of nanostructures (e.g., nanowires) and thus minimize impurity contamination. Catalysts are associated with contamination by undesirable impurities; a few contaminant atoms can lead to large local concentrations and changes in properties.

However, dislocations are nonequilibrium defects; their presence raises the system energy, which is proportional approximately to the square of the magnitude of the Burgers vector. With an increasing magnitude of the Burgers vector of the dislocation, the system can lower its energy by creating a free surface along the core of the dislocation (a hollow core) and stay in a local equilibrium. Frank proposed the formation of hollow cores of screw dislocations for crystal structures with large Burgers vectors. He derived the size of the hollow core by equating the incremental change in strain-energy density by using linear elasticity theory to the change in the surface energy of the hollow core. However, the size of the Burgers vectors obtained was too small to account for experimental observations. By taking into account nonlinear effects empirically, Frank obtained higher values of the Burgers vectors needed to stabilize the formation of hollow cores⁷. However, these estimates still do not correctly take into account the true core energy contributions, which can be handled only by atomistic calculations and not by continuum linear elasticity theory.

Experimentally observed values for the Burgers vectors, however, are considerably higher than these estimates and elementary Burgers vectors derived from crystal structures. This is particularly relevant to hexagonal crystal growth along the c-axis having the largest Burgers vector. Dudley et al. found elementary dislocations in 6H-SiC (c=1.51 nm) were not hollow, and the smallest hollow core dislocation had a Burgers vector of two unit cells (3.0 nm). The Burgers vector in the micropipe was found to have a height of at least four to twelve unit cells (18 nm) to stabilize a hollow core dislocation. More recent work on the growth of ZnO nanotubes likewise demonstrated the role of screw dislocations, but the measured effective Burgers vectors were three to four times higher than the magnitude of c-vectors.

There is another interesting consequence associated with the presence of screw dislocations during crystal growth. Crystal growth is associated with a coaxial screw dislocation inside a finite cylinder; the end surfaces are associated with counteractive shear stresses, which generate the Eshelby twist (a torque and a twist). Since the Eshelby twist is directly proportional to the magnitude of the Burgers vector of the screw dislocation, and inversely to the square of the cylinder radius, it does not play a major role in large size crystals. In contrast, in screw-dislocation aided nanostructure growth (e.g., nanowires), Eshelby twist can provide helically twisted nanostructures with applications in nanoelectronics, nanophotonics, and energy harvesting. Again the same difficulty arose in the interpretation of Eshelby twists. The magnitudes of Burgers vectors experimentally measured for Eshelby twists were considerably larger than the Burgers vectors of elementary screw dislocations.

Associated with the discovery of the double helix, we have solved this longstanding puzzle in the field of dislocations and their role in crystal growth and related phenomena such as Eshelby twist. We showed the transformation of pure screw dislocations into helical dislocations and the formation of a double helix of screw dislocations via the pairing of two helical dislocations (similar to the DNA structure). Here, we describe evidence of the formation of a double helix of screw dislocations in MgO having NaCl structure after thermal annealing, which supplied vacancies. The creation of a double helix may start with a single helical dislocation at the initial stages, where another single dislocation can join subsequently through attractive interaction. Now we can explain the large effective super Burgers vectors needed to rationalize the formation of nanopipes, nanotubes, and micropipes, including large Burgers vectors found in Eshelby twist. We derive the strategy for reducing the formation of nanopipes and micropipes, and discuss the role of single and double helix screw dislocations with Eshelby twists in creating novel nanostructured materials with improved properties.

### SUMMARY

According to an embodiment of the present invention, a process growing crystals in a material is provided. The process comprises a) obtaining a material suitable for an advanced solid-state device, b) heating the material to a process temperature in degrees Kelvin that is between 0.45 and 0.55 times a melting temperature of the material; c) maintaining the process temperature for a period of 30 seconds to 30 minutes to produce a crystalized material, and d) cooling the crystalized material back to room temperature. The material is suitable for an advanced solid-state device. The crystalized material comprises at least one double helix screw dislocation.

### BRIEF DESCRIPTION OF THE DRAWINGS

The present disclosure is illustrated and described herein with reference to the various drawings, in which like reference numbers are used to denote like system components/method steps, as appropriate, and in which:

FIG. 1—(a) A helical screw dislocation at S1 as well as a constant helix angle θ along the dislocation length. (b) double-helix dislocation formation with the dislocation S2; it is shifted by one-quarter of the pitch (λ/4) along the axis. (c) shift in FIG. 1(c) is half (λ/2) of a pitch. (d) TEM micrograph of a double helix with two screw dislocations of a/2 Burgers vector in MgO. An attractive interaction exists between two dislocations via the edge component and vacancy jogs. The TEM samples were prepared by chemical polishing (hot phosphoric acid at 140° C.) without introducing any extraneous damage by ion beam thinning; and

FIG. 2—Formation of stacks of loops from helical screw dislocations due to vacancy diffusion as well as punching into a stack of vacancy loops in (001) MgO after high temperature annealing at 1273 K: (a) TEM micrograph taken with diffraction vector [200], showing a/2 [101] loops at S3 and a/2 [110] loops at S4, and (b) TEM micrograph of the same sample in a different region taken with diffraction vector [200], showing a/2 [110] loops at S4 and a/2 [1−10] loops at S5.

### DETAILED DESCRIPTION

### 1. Results and Discussion

### 1.1. Role of Screw Dislocations

The role of screw dislocations in crystal growth is well established, where they provide a continuous source of available growth sites. Since self-energy of a screw dislocations increases as the square of the Burgers vector in the elastic region, Frank predicted the formation of hollow cores for dislocations with large Burgers vectors, such as screw dislocations along the c-axis in hexagonal crystals of 6H-SiC. These dislocations can lead to the formation of nanopipes and micropipes in hexagonal crystal structures of SiC, GaN, and AlN, which are highly undesirable, known as “killer defects” for light-emitting diodes, high-power, and high-frequency devices. By unraveling the mechanism of formation, we should be able to reduce the number density of nanopipes and micropipes and alleviate their harmful effects. The screw dislocations with hollow cores can also lead to the formation of nanotubes, as observed in the case of ZnO.

Frank proposed the formation of hollow cores of screw dislocations for crystal structures with large Burgers vectors. He considered the change in strain energy density and surface energy of a cylinder along the dislocation in the elastic region. The change in energy, ΔE, equals gain in surface energy minus the corresponding loss in the strain energy,

$$Δ E = 2 πγ dr - ( 1 / 2 {με}^{2} ) 2 π rdr \qquad ( 1 )$$

where μ is the shear modulus, γ is the surface energy of the hollow tube, b is the magnitude of the Burgers vector, and strain ε=b/2πr at the surface of the cylinder of radius r. From dE/dr=0, he derived the radius of the hollow core (r) as,

$$r = μ {b}^{2} / 8 {π}^{2} γ . \qquad ( 2 )$$

By taking into account nonlinear effects empirically, Frank estimated higher magnitudes of Burgers vector in the range of 20πγ/μ to 66πγ/μ for the formation of hollow cores. However, this model involved an unrealistic assumption that for strains greater than 0.1, as those involved in the dislocation core, the strain energy is constant (at μ/200).

An alternative approach to obtain the hollow core radius is based upon minimization of total energy (ET) of the system, including the core energy of the dislocation, where

$${E}_{T} = 2 π r γ + {E}_{c} + μ {b}^{2} / 4 π ( ln R / r ) \qquad ( 3 )$$

Where γ is the surface of the hollow core, E_{c} is the core energy, and the third term is the energy of the dislocation in the linear elastic region. By minimizing (dE_{T}/dr=0), we obtain core radius as

$$r = μ {b}^{2} / [ 4 π ( 2 πγ - α ) ] \qquad ( 4 )$$

where dE_{c}/dr=−α. If we take E_{c} to be constant, we obtain the same result as (2). However, E_{c} needs to be handled by atomistic calculations, as the core energy distortions are nonlinear. From detailed atomistic calculations, the nonlinear dislocation core energy contributions in Si, Ge, and diamond were noted to be a strong function of r, b, and dislocation sense vector. The negative value of α signifies that core distortions decrease with increasing r. Similar calculations are needed for other structures, such as SiC, GaN, and ZnO, to estimate α.

At present, these estimates and experimentally observed values for the Burgers vectors are considerably higher than elementary Burgers vectors derived from the crystal structures. The observation of hollow cores and micropipes in <0001> oriented 6H-SiC (a=0.307 nm, c=1.51 nm), GaN (a=0.319 nm, c=0.519 nm) and ZnO (a=0.325 nm, c=0.520 nm) qualitatively support the concepts proposed by Frank. However, the magnitude of the Burgers vectors associated with nanopipes and micropipes was found to be significantly larger than the respective c-vectors. As discussed in, elementary dislocations in 6H-SiC were not hollow, and the smallest hollow core dislocation had a Burgers vector of two unit cells (3 nm). Others reported that the Burgers vector in the micropipe needs to have a height of at least four to twelve unit cells (18 nm) to stabilize a hollow core dislocation. More recent work on the growth of ZnO nanotubes confirmed the role of screw dislocations, where the effective Burgers vector was measured to be three to four times the magnitude of the c-vectors.

### 1.2. Formation of Single Helix and Double Helix Screw Dislocations

### 1.2.1. Formation of Helical Screw Dislocations

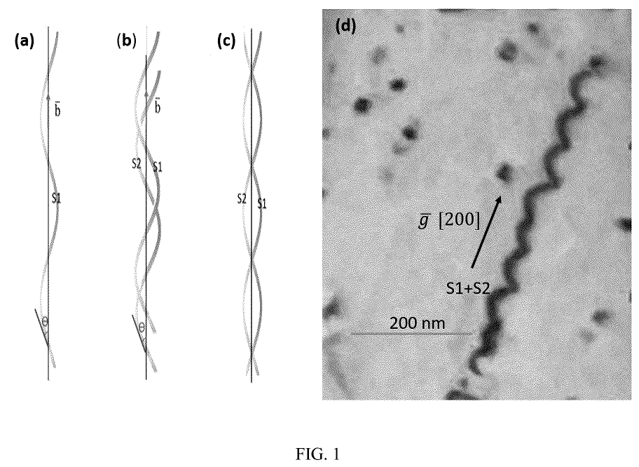

In the following sections, we show that larger effective or super Burgers vectors are possible by the formation of helical screw dislocations, which can pair up to form a double helix and attract additional helical screw dislocations. A pure screw dislocation can attain helicity via dislocation self-climb by absorbing point defects throughout the growth process or thermal annealing, as shown in FIG. 1(a). It is found that the interactions between the hydrostatic stresses of vacancies and the shear stresses of screw dislocations are very weak. It should be noted that local jogs as well as thermal stress fluctuations can introduce local edge components, which are able to interact with the hydrostatic stresses of vacancies. There is an attractive interaction energy between two jogs (Eᵢ); it is given by

$${E}_{i} = μ {b}^{2} {a}^{2} / [ 8 π L ( 1 - v ) ] , \qquad ( 5 )$$

where b is the Burgers vector magnitude, u is the shear modulus, L is the spacing between the jogs, a is the length of the jog, and v is the Poisson's ratio. As the absorption of vacancies continues, the edge component of screw dislocations increases, and the vacancy interactions grow stronger. This causes helix angle θ (as shown in FIG. 1(a)) or helicity to increase to a critical value to balance out the increased dislocation length. The vacancies are uniformly along the helices and their concentration is determined by the radius and the pitch of helices, as discussed below.
The increase in energy per unit length of the helix (ΔEₕ) due to absorption of vacancies is given by

$${( Δ {E}_{h} ) = τ [ \{ {( 2 π {r}_{h} )}^{2} + {λ}^{2} )}^{0.5} / λ \} - 1 ] . \qquad ( 6 )$$

The dislocation line energy (τ) in the helical configuration is expressed as

$$τ = μ {{b}^{2} ( 4 π )}^{- 1} ( 1 + v ) {( 1 - v )}^{- 1} ( ln ( λ / 3 b ) ) . \qquad ( 7 )$$

The number of vacancies absorbed per unit length (N) is directly related to the radius (rₕ) and pitch (λ) of the helix as

$$N = π {{r}_{h}}^{2} b / ( λΩ ) , \qquad ( 8 )$$

where b is the Burgers vector magnitude and Ω is the volume of a vacancy⁹. The helix angle θ (as shown in FIG. 1(a)) stays constant along the entire length of the dislocation; it is related to the radius (rₕ) and pitch (λ) of the helix as θ=tan⁻¹(2πrₕ/λ).
The equilibrium condition as a result of absorption of vacancies is achieved when the change in energy per unit of length of the helix with rₕ equals the change in energy of vacancies which can be expressed as

$$d ( Δ {E}_{h} ) / {dr}_{h} = d ( N Δ {G}_{f} ) / {dr}_{h} \qquad ( 9 )$$

where ΔG_{f} is the formation energy of a vacancy, which is equal to kT ln(c/c₀).

This results in a relationship between supersaturation of vacancies (c/c₀), radius and pitch for the formation of a helix, which is given by

$$kT ln ( c / {c}_{0} ) = 2 πΩτ / [ b {\{ {( 2 π {r}_{h} )}^{2} + {λ}^{2} \}}^{0.5} ] \qquad ( 10 )$$

Here we assume that the sample is quenched from a higher concentration c to lower c₀.

It is seen from equation (10) that {(2πrₕ)²+λ²} is a constant for a particular supersaturation of vacancies; this equation implies that as rₕ decreases, then λ must increase. For very small rₕ, which is expected for the growth of nanostructures, the critical pitch length λ* is provided by

$$λ *= 2 {πΩτ [ bkT ln ( c / {c}_{0} ) ]}^{- 1} . \qquad ( 11 )$$

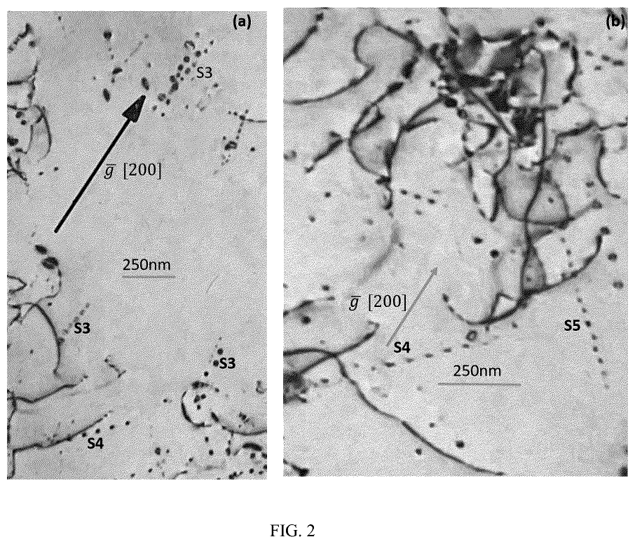

If the pitch λ>λ*, the helix free energy declines with increasing rₕ; the helix grows through absorbing vacancies and turns eventually into a stack of vacancy loops, as shown experimentally below in FIG. 2. However, if λ<λ*, then the diffusion of vacancies via thermal activation is needed to attain the critical value of λ*. Once a helix begins to form, it is unstable with regard to radial growth. For Ω˜b³/4 for GeS (orthorhombic) and b³ for PbS (cubic), τ=20 eV/nm estimated from references^{11,12}, supersaturation c/c₀=10, kT=56 meV [2], then (λ*) is estimated to be 100 nm for Ges⁵, and 120 nm for PbS³ with kT=73 meV. The helix radii are estimated to be over the range from 1 nm to 3 nm for helix angles that vary from 5 to 10 degrees.

### 1.2.2. Formation of Double Helix of Screw Dislocations

The pairing of two pure screw dislocations to account for the experimentally observed larger Burgers vectors has been problematic since two parallel pure screw dislocations exhibit repulsive interactions. The repulsive force (F) is given by F=μb²/(2πr₀), where r₀ is separation between the two dislocations. However, a pure screw dislocation can acquire jogs through the absorption of vacancies, which are present during the growth process. The vacancy absorption imparts an edge component, and the screw component adds helical character. The jogs generated via absorption of vacancies in a helical dislocation interact with those in other helical dislocations. The attractive interaction is a basis for the pairing of two helical dislocations and the formation of a double helix of screw dislocations. Moreover, there is an attractive interaction between two helical dislocations derived via edge components that were obtained via vacancy absorption. This attractive interaction force (F_{A}) per unit length for two parallel edge dislocations may be estimated using

$${F}_{A} = μ {b}^{2} {sin}^{2} θ \cdot cos Φ \cdot cos 2 Φ / [ 2 π ( 1 - v ) r ] , \qquad ( 12 )$$

where θ is the helix angle, b sin θ is the edge component, Φ is the angle between dislocation distance vector r and dislocation plane. F_{A} is attractive (negative) for Φ in the range of 0-45°, and repulsive beyond that.

With the above attractive interactions, we envisage that two helical screw dislocations can pair up to form a double helix of screw dislocations with a larger effective Burgers vector. FIG. 1(b) depicts double helix formation where there is a relative shift by λ/4; for a shift by λ/2, the double helix is provided in FIG. 1(c). Two helical dislocations may alter their relative positions due to their origin and growth conditions. An additional attractive interaction may be derived from vacancy jogs present in the helical dislocations. It is important to note the similarities between single helical screw dislocation (FIG. 1(a)) and single-stranded ribonucleic acid (RNA) molecules as well as between double helix dislocations (FIG. 1(c)) and double-stranded deoxyribonucleic acid (DNA) molecules.

The formation of single helix as a result of vacancy absorption has been studied ever since the first report by Bontinck and Amelinckx. More recently, the formation of single helix dislocations was reported by Haley et al. in Fe-9Cr alloys, where screw dislocations acquired helical character by absorption of vacancies produced by neutron irradiation. Since the neutron damage produced vacancy and interstitial (Frenkel) pairs, the absorption of vacancies by screw dislocations enhanced the clustering of interstitials in the form of loops in the vicinity of helical dislocations. In this study, we describe the formation of the single and double helix screw dislocations in MgO as a function of annealing at high temperatures. Before annealing, these MgO crystals contained a high density of screw, mixed, and edge dislocations associated with a deformation treatment in MgO. Upon thermal annealing at 1273K, which introduced an ample supply of vacancies from the free surface, screw dislocations acquired helical character by absorbing vacancies. The helical dislocations then paired up and formed a double helix, as shown in FIG. 1(d). This micrograph was taken with diffraction vector g=[200], with [001] surface normal. The Burgers vector from g·b and g·bxu contrast analysis was determined to be a/2[101] with sense vector u=[101]. The observed width of the image is consistent with a double helix of screw dislocations. With diffraction vector, dislocation images overlap and give wider images. The double helix in FIG. 1(d) is 780 nm long in the TEM specimen having a thickness of 550 nm. The projected length of the double helix is also 550 nm, as direction makes an angle of 45° with the surface normal [001]. The helical angle for the double helix (from FIG. 1(d)) was estimated to be 35°, which is close to a point where single helix dislocations would be expected to break into stacks of vacancy loops, as discussed below.

The vacancy-dislocation interaction increases with the absorption of vacancies, which in turn increases the attractive edge component consequently. With continued absorption of vacancies, helical dislocations transform into a stack of vacancy loops with separation equal to the pitch and loop radius equal to the radius of the helix, as shown in FIG. 2. From the contrast analysis, it is determined that the stacks of prismatic loops on (101) planes at S3 (FIG. 2(a)) are the product of a single helix originally oriented along the direction and (101) plane, which lies at 45° from the surface normal [001]. The stacks of loops at S4 (FIGS. 2(a) & 2(b)) are derived from an a/2[110] screw dislocation oriented along the direction, whereas the stacks at S5 result from a/2[1−10] screw dislocation laying along the [1−10] direction. These a/2[110] and a/2[1−10] loops lie edge-on in the sample orientation. It is important to note that the length of stacks at S4 and S5 is larger as these dislocations lie nearly parallel to the (001) specimen. From FIG. 2 (S4 and S5), the helix pitch is estimated to be 50 nm and rₕ=5 nm, giving a helix angle of 30-35° and a vacancy supersaturation of (c/c₀) of 2.5 during annealing at 1273K (assuming Ω˜b³ and τ=20 eV/nm). The smaller λ at S5 compared to S4 is consistent with the presence of a double helix and a single helix, respectively, as [(2πrₕ)²+λ²] is constant for a specified supersaturation of vacancies.

The formation of nanopipes and micropipes requires the formation of dislocations with large Burgers vectors. We propose that this can occur by the formation of single helix and double helix of screw dislocations, which can start the nucleation process. Other helical dislocations can then join in through the surface interaction with the hollow core as proposed by Pirouz. From the above discussions about the formation mechanism, we can derive strategies for reducing the number density of nanopipes and micropipes. To reduce the formation of nanopipes and micropipes, we need to reduce the formation of dislocations with large super Burgers vectors. This will require the reduction of the helical dislocations, which can be accomplished by controlling the supply of vacancies via reducing growth temperature during the initial stages of growth. The reduced temperature will also lower the dislocation mobility, which will inhibit the formation of dislocations of larger Burgers vectors. In ZnO, the growth of nanotubes was found to be driven by axial screw dislocations, where self-perpetuating growth spirals enabled the formation of hollow tubes. However, the magnitude of Burgers vector estimated from surface height measurements was found to be 3-4 times higher than the magnitude of elementary Burgers vector (0.520 nm in ZnO). These results can be rationalized by a combination of single helix and double helix of screw dislocations, which develop during the growth of nanotubes.

### 1.3. Impact of Double Helix on Eshelby Twist

In 1953, Eshelby noted that the axial screw dislocation generates a torque in a rod of finite length, which results in an elastic twist in crystalline structures. During growth of a crystal, a coaxial screw dislocation within a finite cylinder with end surfaces generates counteractive shear stresses, which generate an Eshelby twist (a torque and a twist). The Eshelby twist is inversely proportional to the square of the cylinder radius; it does not have a major role in large size crystals. In contrast, in screw dislocation aided nanostructure growth (e.g., nanowires), the Eshelby twist can result in interesting helically twisted nanostructures. Again the same difficulty arose in the interpretation of Eshelby twist. The magnitudes of Burgers vectors derived from experimentally measured Eshelby twists were considerably higher than the Burgers vectors of elementary screw dislocations.

Following the Eshelby twist model, twist per unit length (a) is given by

$$α = - {nb ( π {R}^{2} )}^{- 1} , \qquad ( 13 )$$

where b is the magnitude of the Burgers vector of the screw dislocation, and R is the radius of the nanowire cylinder. The negative sign signifies that the stress, which produces torque for the Eshelby twist, is opposite to that in the bulk, which is required to satisfy the boundary condition of stress zero at the free surface. The Eshelby's formula is not valid at the ends of the cylinder. The length over which Eshelby twist completes its cycle is given by 2π/α. The n=1 case corresponds to Eshelby's original model with a single pure screw dislocation. At the time, the n=2 case was ignored since the pairing of two parallel screw dislocations was deemed unstable due to a repulsive interaction.

In the case of screw dislocations with hollow cores and nanotubes, the Eshelby twist is reduced according to

$$α = - {nb ( π {R}^{2} + π {r}^{2} )}^{- 1} , \qquad ( 14 )$$

where R and r are outer and inner radii of the hollow core structures and nanotubes.
With the introduction of helical dislocations, the Eshelby twist equation for a single helix should be modified to

$$α = - b cos {θ ( π {R}^{2} )}^{- 1} , \qquad ( 15 )$$

where θ is the angle of the helix.
For a double helix, the Eshelby twist equation should be modified to

$$α = - 2 b cos {θ ( π {R}^{2} )}^{- 1} . \qquad ( 16 )$$

where θ is the helix angle, which remains constant along the entire dislocation line.

From their work on PbSe nanowires with NaCl structure, Zhu et al. reported large Eshelby twists, where the magnitude of the Burgers vector (b) was noted to be 1-3 times the Burgers vector [100], instead of normal Burgers vector a/2[110]. The generation of dislocations with a[100] Burgers vector was reported earlier in MgO having the NaCl structure. Similarly, Bierman et al. described screw dislocation nanowire growth in PbS (a NaCl structure with a=0.594 nm) and reported an effective Burgers vector (0.6±0.2 nm) that was much higher (0.42 nm for b=a/2<110>). In nanowires of InP (wurtzite structure with c=0.68 nm), measured Eshelby twist was a factor of two higher than expected from Burgers vectors.

More recent work by Liu et al. involving growth of GeS (an orthorhombic structure with c=1.04 nm) nanowires indicated that axial screw dislocations created a discretized crystallographic twist that occurred along the c-axis. This resulted in helically twisted nanowire structures, which were explained using Eshelby's twist model. However, the effective Burgers vector (b=1.75 nm) was found to be far larger than the b=1.04 nm associated with dislocations, expected from the Eshelby's model. In the following section, we note that the results from these experiments are rationalized by referring to growth via single and double screw dislocations with helical configurations. Since the screw component (b cos θ) of the helical dislocation is involved with the growth process, the double helix effective Burgers vector that contributes to the growth process is 2b cos θ; this value is slightly smaller than 2b. When both single helix and double helix dislocations contribute to the growth process, we can write

$$2 δ b cos θ + ( 1 - δ ) b cos θ = be \qquad ( 17 )$$

In this equation, δ is the fraction of double helix, θ is the angle of the helix, (1−δ) is the fraction of single helix, and be is an experimentally observed average value for the Burgers vector. In the case of GeS growth⁵ where b=1.04 nm and be=1.75 nm, δ was noted to be 71% and 69% with helix angle values of 10 and 5 degrees, respectively. For PbS with b=0.4 2 nm and be=0.6 nm, δ was calculated as 45% and 43% with helix angle values of 10 and 5 degrees, respectively. To describe a higher level of double helices in GeS than in PbS, it should be noted that GeS exhibits orthorhombic (pseudo hexagonal) structure; the major dislocations involved in the growth process are c-dislocations. The screw dislocations are able to significantly reduce their energy by growing in <0001> directions. On the other hand, PbS exhibits a cubic NaCl structure (as in MgO), in which there are no dominating Burgers vectors for screw dislocations. As such, growth in PbS takes place along the <100> direction with mixed a/2<110> dislocations. In the case of PbS³ (NaCl or MgO structure), it is envisaged that the core of an a dislocation splits into a/2[110] and a/2[1−10] dislocations, as demonstrated for MgO. Here two a/2[110] and a/2[1−10] Burgers vectors combine to provide effective a [100] Burgers vector during crystal growth along direction. This is equivalent to δ=1, and θ=45° in equation (17); we obtain be=0.594 nm, which is in good agreement with the experimental observations of 0.6 nm for PbS.

In summary, we have shown the impact that a single helix and double helix of screw dislocations can have on crystal growth and formation of nanostructures in solid state materials. Screw dislocations can have critical role in the growth of crystalline structures by providing a continuous source of surface steps, which represent available sites for crystal growth. However, experimentally derived Burgers vectors are found to be far larger than elementary Burgers vectors derived from the crystal structures. This longstanding puzzle has been solved with the discovery of stable double helices of screw dislocations. Two parallel straight screw dislocations exhibit a repulsive interaction and cannot pair up to increase the magnitude of the effective Burgers vector. However, attractive interactions can develop, if these screw dislocations take on a helical character. We have shown that pure screw dislocations can become helical by the absorption of defects (e.g., vacancies), and develop attractive interactions with another helical dislocation to form a double helix of screw dislocations. The single helix and double helix of screw dislocations can also combine to create even larger effective Burgers vectors and lead to the formation of interesting nanostructures with large Eshelby twists. These large effective Burgers also unravel the mechanism of formation of nanopipes and micropipes with hollow cores and nanotubes with Eshelby twist in technologically important materials, which are needed for realizing a variety of advanced solid state devices ranging from light emitting diodes to high-frequency and high-power devices. The role of screw of screw dislocations in crystal growth is quite pervasive across the scale from nanoscale to mesoscale. The chiral shapes in tellurium nanostructures are found to result from screw-dislocation-mediated growth. The handedness (left or right) of the shape seems to be dictated by screw dislocations. Screw dislocations within the seed during crystal growth can also provide a template for spiral self-organization and the growth of metastable phases. In MgZn₂, the metastable Laves phase was found to nucleate from the liquid, with screw dislocations that intersected solid-liquid interfaces, thus catalyzing the spiral growth of the two-phase microstructure. In view of the formation of defect-mediated helical dislocations and double helices, it should be interesting to see how the helicity of a screw dislocation affects the chirality of grown crystals and the formation of novel metastable phases. Thus, the discovery of double helix of screw dislocations stands to impact our understanding of crystal growth and the formation of crystalline structures across the nanoscale to mesoscale for next generation solid state devices.

Although the present invention has been illustrated and described herein with reference to preferred embodiments and specific examples thereof, it will be readily apparent to those of ordinary skill in the art that other embodiments and examples may perform similar functions and/or achieve like results. All such equivalent embodiments and examples are within the spirit and scope of the present invention and are intended to be covered by the following claims.

What is claimed is:

1. A process for growing crystals in a material, the process comprising
a) obtaining a material;
b) heating the material to a process temperature in degrees Kelvin that is between 0.5 and 0.9 times a melting temperature of the material;
c) maintaining the process temperature for a period of 30 seconds to 30 minutes to produce a crystalized material; and
d) cooling the crystalized material back to room temperature,
wherein the material is suitable for an advanced solid-state device and
wherein the crystalized material comprises at least one double helix screw dislocation.

2. The process of claim 1, wherein the material comprises silicon carbide, gallium nitride, zinc oxide, magnesium oxide, lead selenide, lead sulfide, indium phosphide, and/or germanium monosulfide; or wherein the material is selected from the group consisting of silicon carbide, gallium nitride, zinc oxide, magnesium oxide, lead selenide, lead sulfide, indium phosphide, or germanium monosulfide.

3. The process of claim 1, wherein a helix angle θ along the at least one double helix screw locations is approximately 35°; or wherein a helix angle θ along the at least one double helix screw locations ranges from 25° to 45°.

4. The process of claim 1, wherein the crystalized material is at least 5% to 50% harder than the material as measured using the Rockwell test.

5. A crystallized material produced by
a) obtaining a material selected from the group consisting of silicon carbide, gallium nitride, zinc oxide, magnesium oxide, lead selenide, lead sulfide, indium phosphide, or germanium monosulfide;
b) heating the material to a process temperature in degrees Kelvin that is between 0.45 and 0.55 times a melting temperature of the material;
c) maintaining the process temperature for a period of 30 seconds to 30 minutes to produce a crystalized material; and
d) cooling the crystalized material back to room temperature
wherein, the crystalized material comprises at least one double helix screw dislocation.

6. These helical dislocations improve strength and hardness of materials by lowering the mobility of dislocations, and electrical and chemical properties through the charge states of vacancies. The vacancies in certain materials can act as qubits and uniform distribution of vacancies (qubits) along helical dislocations can lead to entangled quantum system needed for quantum devices.
